(19) United States
(12) Patent Application Publication
(10) Pub. No.: US 2008/0213675 A1
(43) Pub. Date: Sep. 4, 2008

(54) Interrogation of a Light-Sensitive Sensor

(76) Inventors: Satyamoorthy Kabilan, Cambridge (GB); Alexander James Marshall, Cambridge (GB)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/996,253

(22) PCT Filed: Jul. 18, 2006
(86) PCT No.: PCT/GB06/02673

§ 371 Date: May 20, 2008

(30) Foreign Application Priority Data
Jul. 19, 2005 (GB) PCT/GB2005/002861
Jan. 13, 2006 (GB) 0600697.7

(51) Int. Cl. G03F 1/14

(52) U.S. Cl. 430/2

(57) ABSTRACT

A sensing method comprises irradiating a sensor having a medium including a light-sensitive holographic element, and observing a change in the holographic image.

### FIELD OF THE INVENTION

This invention relates to a method for changing an optical characteristic of a holographic sensor.

### BACKGROUND TO THE INVENTION

Holographic sensors may be used for the detection of a variety of analytes. WO95/26499 discloses a holographic sensor, based on a volume hologram. This sensor comprises an analyte-sensitive matrix having an optical transducing structure disposed throughout its volume. Because of this physical arrangement of the transducer, an optical signal generated by the sensor is very sensitive to volume changes or structural rearrangements taking place in the analyte-sensitive matrix as a result of interaction or reaction with the analyte.

WO03/087899 describes a method of continuous sensing using a holographic sensor. A fluid comprising the analyte is passed over the sensor, the analyte reacting reversibly with the holographic support medium.

### SUMMARY OF THE INVENTION

The present invention is based on the realisation that a holographic sensor can usefully be sensitive to light. The sensor, e.g. a volume hologram in which a medium supporting a hologram is affected by light, undergoes a change that can be observed. This change in an optical characteristic can be irreversible or reversible.

According to the invention, a sensing method comprises subjecting a light-sensitive holographic sensor to light and observing a change in the image. The “light” may be understood as remote or direct interrogation that induces a variation in a physical or chemical property of a medium in which a holographic element is supported.

The invention has particular relevance to security/authentication, e.g. in tamper-proofing. The observed change, i.e. a change in the optical characteristic of the sensor, may be detectable either directly by eye, or using any suitable apparatus, for example a spectrometer.

### BRIEF DESCRIPTION OF THE DRAWING

FIG. 1 is a graph of intensity (counts) against time (mins).

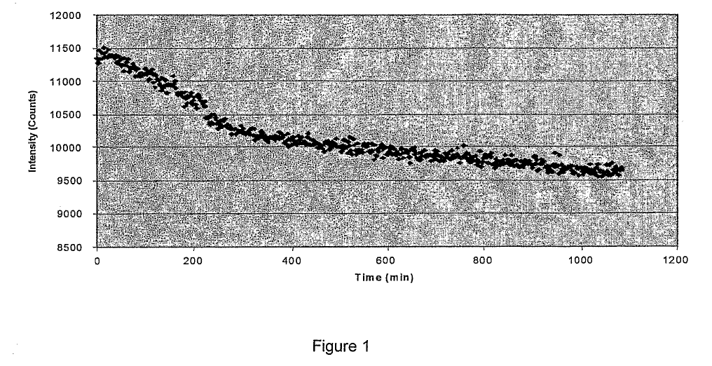

### DESCRIPTION OF THE INVENTION

A holographic sensor for use in the invention typically comprises a holographic support medium and, disposed throughout the volume of the medium, a hologram. A method of the invention preferably involves the use of a sensor wherein the support medium is light-sensitive. By subjecting the sensor to interrogation, the (local) physical or chemical property may be changed, causing a change in a property of a component of the sensor, e.g. the support medium or a material within it. This results in a change in an optical characteristic of the element.

The sensor may be interrogated by any suitable means. As an example of remote interrogation, a laser of suitable power, when directed at the sensor, may cause the support medium to expand. A sensor of the invention may thus be light-addressable.

The property of the support medium that varies may be its charge density, volume, shape, density, viscosity, strength, hardness, charge, hydrophobicity, swellability, integrity, cross-link density or any other physical property. Variation of such a property causes a variation of an optical characteristic, such as polarisability, reflectance, refractance or absorbance of the holographic element. If any change occurs whilst the hologram is being replayed by incident broad band, non-ionising electromagnetic radiation, then an optical property varies and a colour or intensity change, for example, may be observed.

The property that varies is preferably the size or volume of the support medium. This may be achieved by incorporating into the support matrix, groups which cause an expansion or contraction of the support medium. The support medium preferably comprises a native or modified matrix with viscoelastic properties.

In a preferred embodiment, the support medium comprises a spiropyran group, or a derivative thereof. Spiropyrans, upon exposure to UV light, undergo a reversible conversion to merocyanine. This transformation is accompanied by an increase in charge, and may cause the support medium to expand. The conversion can be reversed by interrogating the sensor with visible light or heat.

The holographic sensor may comprise a plurality of holographic elements, each element being sensitive to a different property. The holographic elements may be in the form of an array.

The hologram may be, for example, a transmission or reflection hologram. In a reflection hologram, the fringes are parallel to a surface of the support medium; this causes rays to leave by the same surface at which the incident rays enter.

The sensitivity of the sensor to external physical interaction may be the consequence of the bulk properties of the sensor or support medium. Alternatively, it may be the consequence of chemical or other modification of the holographic element; this may be particularly appropriate for more sensitive reaction and/or to remote interrogation.

By way of illustration, the sensor can be treated so that a component undergoes a chemical reaction in response to light. For example, silver grains used in forming the holographic element can be treated to form photosensitive fringes.

As illustrated in the Example, a light-sensitive hologram can be fabricated by subjecting the sensor to interrogation by light, and the properties of the hologram are altered in such a way that a change in an optical characteristic of the holographic element occurs. In the Example, a particular bleach is used, but it will be understood that others are suitable. Modification of the bleaching protocol and/or of the backbone of a polymer used in the median can be used to modulate photosensitivity. Similarly, other influences can be used to modulate sensitivity and thus the response of the sensor.

Light-sensitive holographic sensors may also be fabricated using an azobenzene moiety which undergoes a trans to cis photoisomerization under UV interrogation. This changes the free energy of mixing of the medium supporting the holographic image and therefore results in a change in the optical properties of the associated hologram. Yet another approach involves the use of triphenylmethane leuco dyes incorporated into the holograms. Such dyes photo-dissociate in the presence of UV light, resulting in a charged species which causes the holographic matrix to swell, altering the holographic image.

Particularly for a laser-sensitive sensor, the medium is preferably a polymer comprised of elastomeric monomers.

The invention is particularly relevant to security. For example, an authentication tag may comprise a holographic sensor having a built-in “message”. When the sensor is interrogated, the sensor displays the “message”. The “message” is preferably viewable directly by eye.

The sensor may be sensitive to an analyte which is a chemical, biochemical or biological species. The present invention relates to a method of detection of any such analyte in a sample, which comprises contacting the sample with the sensor, and detecting any change of its optical characteristic.

The present invention also relates to an article comprising a sensor according to the invention where the article is a device such as a transaction card, banknote, passport, identification card, smart card, driving license, share certificate, bond, cheque, cheque card, tax banderole, gift voucher, postage stamp, rail or air ticket, telephone card, lottery card, event ticket, credit or debit card, business card, or an item used in consumer, brand or product protection for the purpose of distinguishing genuine products from counterfeit products or identifying stolen products. The article can also be an item of intelligent packaging which is a system that comprises a container, wrapper or enclosure to monitor, test or indicate product information on quality or environmental conditions that will affect product quality, shelf life or safety. Typical applications include indicators showing time-temperature, freshness, moisture, alcohol, gas, physical damage and the like.

The article can be an industrial or handicraft item comprising a decorative element, selected from items of jewelry, items of clothing (including footwear), fabric, furniture, toys, gifts, household items (including crockery and glassware), architecture (including glass, tile, paint, metals, bricks, ceramics, wood, plastics and other internal and external installations), art (including pictures, sculpture, pottery and light installations), stationery (including greetings cards, letterheads and promotional material) and sporting goods. The article can be a product or device for use in agricultural studies, environmental studies, human or veterinary prognostics, theranostics, diagnostics, therapy or chemical analysis which can be a test strip, chip, cartridge, swab, tube, pipette, contact lens, sub-conjunctival implant, sub-dermal implant, breathalyzer, catheter or a fluid sampling or analysis device.

The invention also relates to a transferable holographic film comprising a sensor according to the invention. The film can be present on a hot stamping tape or can be used to enhance the security of an article, by transferring onto the article the sensor from the film.

The present invention further relates to a product comprising a sensor of the invention which is capable of generating data and a system which uses such data for data reading, processing, storage, control, transmission, distributing, reporting and/or modelling. Such systems include mobile telephones, personal digital assistants and other portable electronic devices.

The following Example illustrates the invention.

### EXAMPLE

A light-sensitive holographic sensor was fabricated from a gelatin-based hologram. The resultant hologram was bleached using a Fe(III)-based formulation with KBr, to create photosensitive holographic fringes. The light-sensitive holographic sensor was then exposed to white light for 1000 min and the intensity of the light diffracted by the hologram was monitored and recorded for the duration of the experiment, as shown in the accompanying drawing. The intensity of the diffracted signal (reflectivity) was observed to decrease by 15% during the first 200 min of exposure to white light. Furthermore, this effect was visible to the naked eye.

1. A sensing method which comprises irradiating a sensor having a medium including a light-sensitive holographic element, and observing a change in the holographic image.

2. The method according to claim 1, wherein the change in the optical characteristic is reversible.

3. The method according to claim 1, wherein the change in the optical characteristic is irreversible.

4. The method according to claim 1, wherein a component of the sensor undergoes a chemical reaction in response to light.

5. The method according to claim 4, where the sensor is formed by bleaching a volume hologram, to give photosensitive holographic fringes.

6. The method according to claim 1, wherein the medium comprises a spiropyran or merocyanine group.

7. The method according to claim 1, wherein the size, shape, density, viscosity, strength, hardness, hydrophobicity, swellability, integrity, polarisability and/or charge distribution of the medium changes on irradiation with light.

8. The method according to claim 1, wherein the medium comprises a polymer.

9. The method according to claim 8, wherein the polymer is elastomeric.

10. The method according to claim 1, wherein the hologram comprises a reflection or transmission hologram.

11. The method according to claim 1, wherein the hologram is viewable under white light, UV light or infra-red radiation.

12. The method according to claim 1, wherein the sensor is a transaction card, banknote, passport, identification card, smart card, driving license, share certificate, bond, cheque, cheque card, tax banderole, gift voucher, postage stamp, rail or air ticket, telephone card, lottery card, event ticket, credit or debit card, business card, or an item used in consumer, brand or product protection for the purpose of distinguishing genuine products from counterfeit products or identifying stolen products.

13. The method according to claim 1, wherein the sensor is an item of intelligent packaging as defined herein.

14. The method according to claim 1, wherein the sensor is an industrial or handicraft item comprising a decorative element, selected from items of jewelery, items of clothing, fabric, furniture, toys, gifts, household items, architecture, art, stationery and sporting goods.

15. The method according to claim 1, wherein the sensor is a product or device for use in agricultural studies, environmental studies, human or veterinary prognostics, theranostics, diagnostics, therapy or chemical analysis.

16. The method according to claim 15, which is a test strip, chip, cartridge, swab, tube, pipette, contact lens, sub-conjunctival implant, sub-dermal implant, breathalyzer, catheter or fluid sampling or analysis device.
